(19) United States
(12) Patent Application Publication
(10) Pub. No.: US 2024/0337016 A1
(43) Pub. Date: Oct. 10, 2024

(54) LASER-TREATED ANTI-DEPOSITION OBJECT AND MANUFACTURING METHOD OF THE SAME

(71) Applicant: HIGHLIGHT TECH CORP., Tainan City (TW)

(72) Inventors: CHIEN-CHENG CHANG, Tainan City (TW); HE-PU LU, Tainan City (TW); CHIEN-HSUN CHEN, Tainan City (TW); CHIH-CHIANG FANG, Tainan City (TW)

(73) Assignee: HIGHLIGHT TECH CORP., Tainan City (TW)

(21) Appl. No.: 18/229,176

(22) Filed: Aug. 2, 2023

(30) Foreign Application Priority Data
Apr. 10, 2023 (TW) 112113323
Jun. 2, 2023 (TW) 112120700

(51) Int. Cl. C23C 16/44; B23K 26/352; C23C 16/455

(52) U.S. Cl. CPC C23C 16/4404; B23K 26/352; C23C 16/45544

(57) ABSTRACT

Disclosed are a laser-treated anti-deposition object with a main structure and a fluorine coating layer and a manufacturing method of the same. The fluorine coating layer covers a laser-treated surface of the main structure to form an anti-deposition surface, an initial surface of the main structure is subjected to a laser surface treatment step by a laser to become the laser-treated surface with a plurality of microstructures. The anti-deposition object contacts with a manufacturing process substance used or discharged during a manufacturing process performed by a manufacturing process equipment in a vacuum environment, and the anti-deposition surface of the object has a relatively high contact angle.

### CROSS-REFERENCE TO RELATED APPLICATION

This application claims priority from Taiwan Patent Application No. 112113323, filed on Apr. 10, 2023; and claims priority from Taiwan Patent Application No. 112120700, filed on Jun. 2, 2023, each of which is hereby incorporated herein by reference in its entireties.

### BACKGROUND OF THE INVENTION

### 1. Field of Invention

The invention relates to vacuum component, and more particularly to a laser-treated anti-deposition object.

### 2. Related Art

In recent years, due to the continuous vigorous development of semiconductor technology, technological products have made great progress. In the manufacturing process of semiconductor chips, the chip is usually placed in a manufacturing process equipment for related process operations, and a vacuum pump is used to extract the air or gas in the manufacturing process equipment to keep the manufacturing process equipment in a negative pressure state, that is, in a certain degree of vacuum. However, in the semiconductor manufacturing process, manufacturing process substances such as process gases or process exhaust gases could be easily deposited or accumulated in the fluid channel, which leads to shorter and shorter maintenance cycles to affect manufacturing costs and schedules.

### SUMMARY OF THE INVENTION

In view of the above, one object of the invention is to provide a laser-treated anti-deposition object and a manufacturing method of the same to solve the above-mentioned problems in the prior art.

In order to achieve the aforementioned object, the invention provides a laser-treated anti-deposition object, the anti-deposition object contacting with a manufacturing process substance used or discharged during a manufacturing process performed by a manufacturing process equipment in a vacuum environment, the anti-deposition object comprising: a main structure, at least one initial surface of the main structure being subjected to a laser surface treatment step by a laser to become a laser-treated surface with a plurality of microstructures; and a fluorine coating layer, the fluorine coating layer covering the microstructures of the laser-treated surface of the main structure in order to serve as an anti-deposition surface of the main structure, wherein the initial surface and the laser-treated surface of the main structure are hydrophilic surfaces, a hydrophilicity of the laser-treated surface is higher than a hydrophilicity of the initial surface, and the anti-deposition surface is a hydrophobic surface, so that the anti-deposition surface has a contact angle to the manufacturing process substance higher than those of the initial surface and the laser-treated surface of the main structure.

In order to achieve the aforementioned object, the invention further provides a manufacturing method of a laser-treated anti-deposition object, the anti-deposition object contacting with a manufacturing process substance used or discharged during a manufacturing process performed by a manufacturing process equipment in a vacuum environment, the manufacturing method comprising following steps of: providing a main structure, wherein the main structure has at least one initial surface; performing a laser surface treatment step on the initial surface of the main structure by using a laser, so that the initial surface becoming a laser-treated surface with microstructures; and performing a fluorine coating step for covering the microstructures of the laser-treated surface of the main structure by a fluorine coating layer in order to form an anti-deposition surface on the main structure, wherein the initial surface and the laser-treated surface of the main structure are hydrophilic surfaces, a hydrophilicity of the laser-treated surface is higher than a hydrophilicity of the initial surface, and the anti-deposition surface is a hydrophobic surface, so that the anti-deposition surface has a contact angle to the manufacturing process substance higher than those of the initial surface and the laser-treated surface of the main structure.

In order to enable the examiner to have a further understanding and recognition of the technical features of the invention and the technical efficacies that can be achieved, preferred embodiments in conjunction with detailed explanation are provided as follows.

### BRIEF DESCRIPTION OF THE DRAWINGS

FIG. 1 is a schematic diagram of a partial structure of a laser-treated anti-deposition object of the invention.

FIG. 2 is a flow chart of manufacturing procedures of the laser-treated anti-deposition object of the invention.

FIGS. 3A to 3C are cross-sectional views of the manufacturing procedures of the laser-treated anti-deposition object of the invention.

FIG. 4 is a schematic diagram of application of the laser-treated anti-deposition object of the invention to a manufacturing process equipment.

FIG. 5 is a cross-sectional structural view of a first implementation example of the laser-treated anti-deposition object of the invention.

FIG. 6 is a cross-sectional structural view of a second implementation example of the laser-treated anti-deposition object of the invention.

FIG. 7 is a cross-sectional structural view of a third implementation example of the laser-treated anti-deposition object of the invention.

FIG. 8 is a perspective structural view of a fourth implementation example of the laser-treated anti-deposition object of the invention.

### DETAILED DESCRIPTION OF THE INVENTION

In order to understand the technical features, content and advantages of the invention and its achievable efficacies, the invention is described below in detail in conjunction with the figures, and in the form of embodiments, the figures used herein are only for a purpose of schematically supplementing the specification, and may not be true proportions and precise configurations after implementation of the invention; and therefore, relationship between the proportions and configurations of the attached figures should not be interpreted to limit the scope of the claims of the invention in actual implementation. In addition, in order to facilitate understanding, the same elements in the following embodiments are indicated by the same referenced numbers. And the size and proportions of the components shown in the drawings are for the purpose of explaining the components and their structures only and are not intending to be limiting.

Unless otherwise noted, all terms used in the whole descriptions and claims shall have their common meaning in the related field in the descriptions disclosed herein and in other special descriptions. Some terms used to describe in the present invention will be defined below or in other parts of the descriptions as an extra guidance for those skilled in the art to understand the descriptions of the present invention.

The terms such as “first”, “second”, “third” and “fourth” used in the descriptions are not indicating an order or sequence, and are not intending to limit the scope of the present invention. They are used only for differentiation of components or operations described by the same terms.

Moreover, the terms “comprising”, “including”, “having”, and “with” used in the descriptions are all open terms and have the meaning of “comprising but not limited to”.

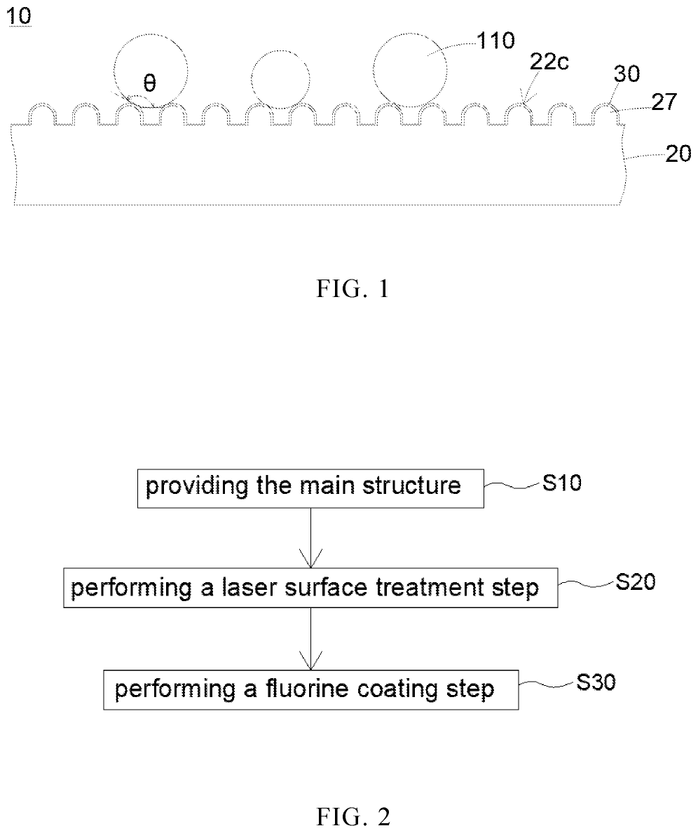

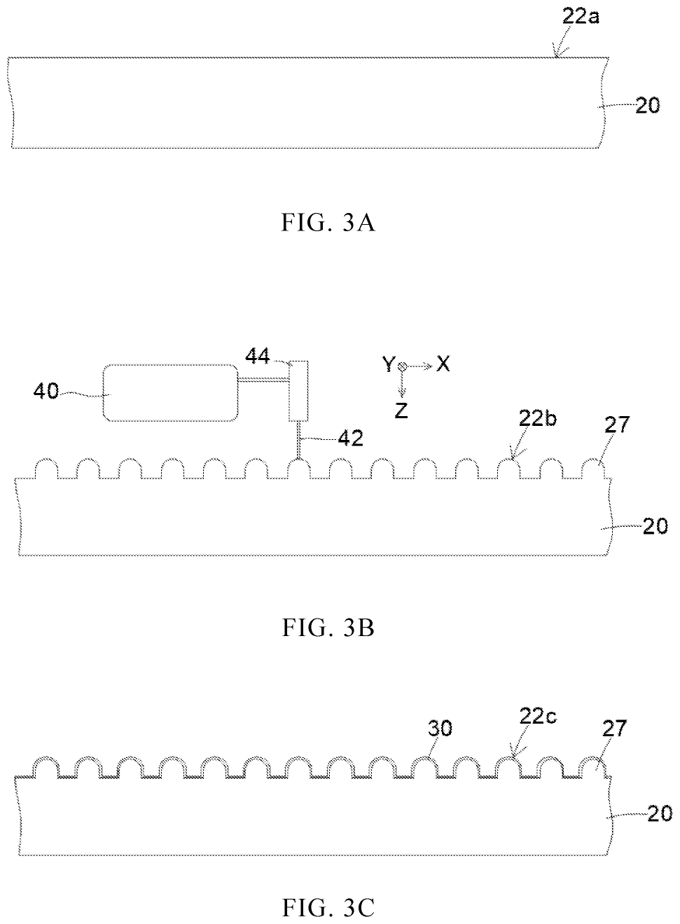

Since a manufacturing process equipment uses or discharges a lot of manufacturing process substances when performing various semiconductor manufacturing processes, and it is quite easy for these manufacturing process substances to deposit on pipe fittings or pipe walls where they contact with, in order to avoid deposition of the manufacturing process substances, the invention provides a laser-treated anti-deposition object and a manufacturing method of the same, and the anti-deposition object has a relatively high contact angle (also called water drop contact angle or water drop angle). Moreover, compared to a surface with only a rough structure or only a fluorine coating layer, an anti-deposition surface of the anti-deposition object has a higher contact angle, which means it has super-hydrophobic and super-oleophobic effects. FIG. 1 is a schematic diagram of a partial structure of a laser-treated anti-deposition object of the invention. FIG. 2 is a flow chart of manufacturing procedures of the laser-treated anti-deposition object of the invention. FIGS. 3A to 3C are cross-sectional views of the manufacturing procedures of the laser-treated anti-deposition object of the invention.

Please refer to FIG. 1 to FIGS. 3A to 3C, a laser-treated anti-deposition object 10 of the invention comprises a main structure 20 and a fluorine coating layer 30, wherein the main structure 20 has a rough structure (that is, a plurality of microstructures 27) produced by laser surface treatment, the fluorine coating layer 30 covers the microstructures 27 of the main structure 20 to form an anti-deposition surface 22c. The microstructures 27 are, for example, arranged on the main structure 20. The invention is illustrated by the microstructures 27 arranged at intervals, wherein the microstructures 27 are, for example, a plurality of convex ribs extending along a Y-axis direction and arranged on the main structure 20 along an X-axis direction, a shape of a top thereof could be arc-shaped, semi-arc-shaped, planar, inclined, irregular or other shapes as shown in FIG. 1, and an interval between the adjacent microstructures 27 is, for example, a laser scanning interval, but the invention is not limited thereto, the microstructures 27 could also be arranged in a dot-matrix manner, for example. Alternatively, the microstructures 27 could also be abutting against one another, which means that as long as an effect of increasing the contact angle of the invention could be achieved, the microstructures 27 of any shape or any arrangement type belong to a scope of protection claimed by the invention. In addition, the invention is illustrated by the fluorine coating layer 30 covering surfaces of the microstructures 27 of the main structure 20 conformally, which means that the fluorine coating layer 30 covers the main structure 20 along with the microstructures 27, and covers the main structure 20 between the adjacent microstructures 27, but the invention is not limited thereto, as long as an effect of increasing the contact angle of the invention could be achieved, any covering manner belongs to a scope of protection claimed by the invention.

In the manufacturing method of the laser-treated anti-deposition object 10 of the invention, as shown in FIG. 2 and FIG. 3A, firstly, providing the main structure 20 (step S10), wherein the main structure 20 has at least one initial surface 22a. Then, as shown in FIG. 2 and FIG. 3B, performing a laser surface treatment step (step S20) on the initial surface 22a of the main structure 20 by using a laser 42, so that the initial surface 22a becomes a laser-treated surface 22b with the microstructures 27. Wherein, one laser 42 or multiple lasers 42 is/are generated by means of a laser generator 40, for example, the laser 42 is a pulsed light, and the laser 42 is transmitted to the initial surface 22a of the main structure 20 through a lens 44, for example, and is capable of moving along the X-axis, Y-axis or Z-axis direction. By modifying the initial surface 22a of the main structure 20 made of remelted stainless steel, for example, to generate nanometer-scale wrinkles, which are the microstructures 27, is capable of producing a larger total contact area (roughness). Wherein, the laser generator 40 is, for example, a Nd:YAG laser generator, but the invention is not limited thereto. Then, as shown in FIG. 2 and FIG. 3C, performing a step of covering the laser-treated surface 22b of the main structure 20 by the fluorine coating layer 30 (step S30) to cover the microstructures 27 of the laser-treated surface 22b of the main structure 20 by the fluorine coating layer 30 to form the anti-deposition surface 22c on the main structure 20. A characteristic of the invention is that the initial surface 22a of the main structure 20 is subjected to the laser surface treatment step (step S20) by using the laser 42 to become the laser-treated surface 22b with the microstructures 27. Wherein, if the initial surface 22a of the main structure 20 is hydrophilic (the contact angle is about 80˜86 degrees), then after the laser surface treatment step (step S20) by using the laser 42, a hydrophilicity of the laser-treated surface 22b of the main structure 20 will be enhanced to super-hydrophilic (the contact angle is less than 20 degrees). On the contrary, if the initial surface 22a of the main structure 20 is hydrophobic, then after the laser surface treatment step (step S20) by using the laser 42, a hydrophobicity of the laser-treated surface 22b of the main structure 20 will increase. However, after covering the super-hydrophilic laser-treated surface 22b by the fluorine coating layer 30 in the invention, the anti-deposition surface 22c formed will have a super hydrophobicity (a contact angle θ is about greater than 130 degrees), and the contact angle θ of the anti-deposition surface 22c of the invention could even be greater than or equal to about 150 degrees, and a sliding angle thereof is less than or equal to about 10 degrees. The sliding angle refers to an inclination angle of the anti-deposition object 10 capable of causing sliding of droplets when the droplets drop on the inclined anti-deposition object 10 by performing a droplet (such as water drop) impact test with a needle at a height of about 90 mm from the anti-deposition object 10. The smaller the sliding angle, the better an anti-deposition effect of the anti-deposition object 10.

In the laser surface treatment step (step S20) by using the laser 42, an energy density of the laser 42 irradiating the initial surface 22a of the main structure 20 (that is, the laser 42 makes the main structure 20 generate the microstructures 27) could be any value or interval ranges from about 0.01 W/cm² to about 110 W/cm² in order to form the microstructures 27 on the main structure 20, wherein the microstructures 27 preferably have independent peaks, so that when the fluorine coating layer 30 covers surfaces of the microstructures 27 of the main structure 20 conformally subsequently, the formed anti-deposition surface 22c still retains a morphology of the microstructures 27, so the above-mentioned conformal could also be referred to as maintaining shape. Wherein, a scanning speed of the laser 42 is any value or interval from 50 mm/s to 100 mm/s. Taking the laser generator 40 capable of generating the lasers 42 spaced along the Y-axis direction as an example, the scanning speed mentioned above is, for example, a moving speed of the lasers 42 in the X-axis direction. A scanning frequency of the lasers 42 is any value or interval from 10 kHz to 40 kHz; a pulse width of the lasers 42 is any value or interval from 20 ns to 200 ns; a laser scanning interval of the lasers 42 is any value (for example, 10 μm, 20 μm, 30 μm, 40 μm, 50 μm, 80 μm, 100 μm, 200 μm) or interval from 10 μm to 200 μm; and a number of times of scanning of the lasers 42 could be 1 time or more than 1 time. Wherein, a power of the lasers 42 ranges from 10 watts to 100 watts, for example, 10 watts, 15 watts, 20 watts, and so on, a wavelength of the lasers 42 ranges from 380 nm to 1400 nm, for example, 380 nm to 420 nm, 445 nm to 473 nm, 532 nm, 633 nm, 785 nm to 1064 nm. A person having ordinary skill in the art to which the invention pertains could select appropriate parameters and combinations thereof according to the content disclosed in the invention to obtain a required contact angle, wherein a range of the contact angle θ of the invention could be from about 99 degrees to about 150.2 degrees.

Another characteristic of the invention is that the fluorine coating layer 30 covers the microstructures 27 of the laser-treated surface 22b of the main structure 20 to form the anti-deposition surface 22c on the main structure 20, that is, using the fluorine coating layer 30 as the anti-deposition surface 22c of the main structure 20. Yet another characteristic of the invention is that the initial surface 22a and the laser-treated surface 22b of the main structure 20 are hydrophilic surfaces, a hydrophilicity of the laser-treated surface 22b is higher than a hydrophilicity of the initial surface 22a, and the anti-deposition surface 22c is a hydrophobic surface, so that the anti-deposition surface 22c has a contact angle to manufacturing process substances higher than those of the initial surface 22a and the laser-treated surface 22b of the main structure 20. Taking the main structure 20 made of stainless steel as an example, such as various types of 304 stainless steel plates available in the market, the initial surface 22a of the main structure 20 is hydrophilic (the contact angle is about 80˜86 degrees), after the laser surface treatment step (step S20) by using the laser 42, a hydrophilicity of the laser-treated surface 22b of the main structure 20 will be enhanced to a super-hydrophilicity (the contact angle is less than about 20 degrees). However, after being covered with the fluorine coating layer 30, the anti-deposition surface 22c formed will have a super-hydrophobicity (the contact angle is greater than about 130 degrees). The contact angle of the anti-deposition surface 22c of the invention ranges from about 99 degrees to about 150.2 degrees, that is, the contact angle could be greater than or equal to 150 degrees, and the sliding angle is less than or equal to 10 degrees.

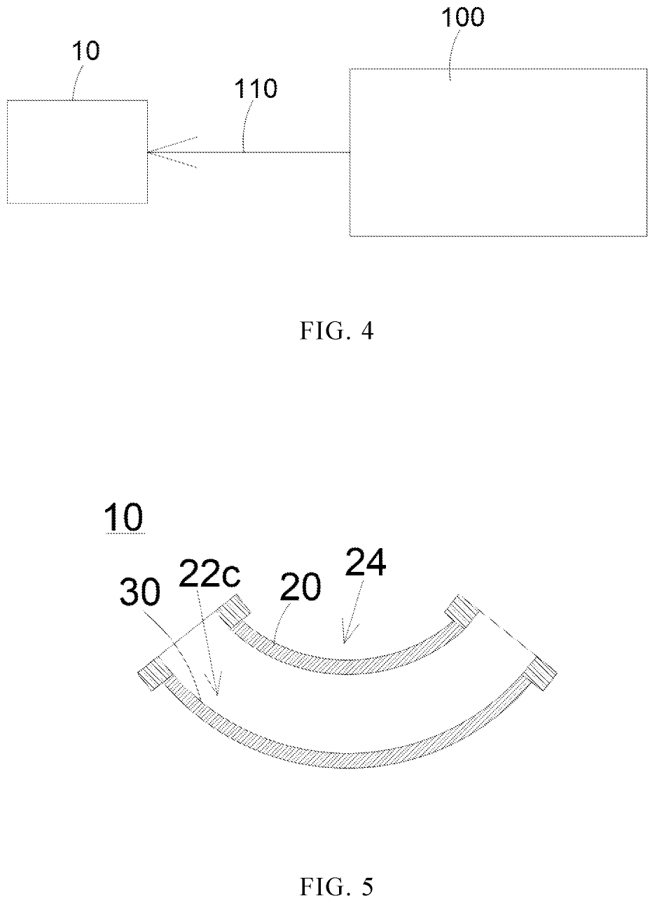

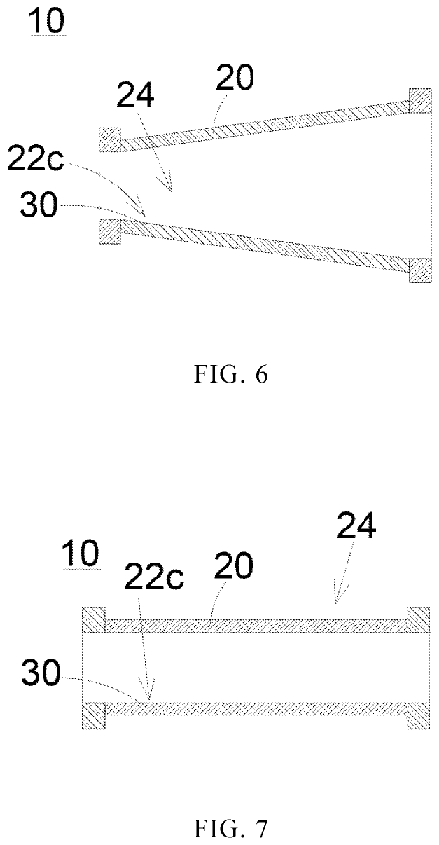

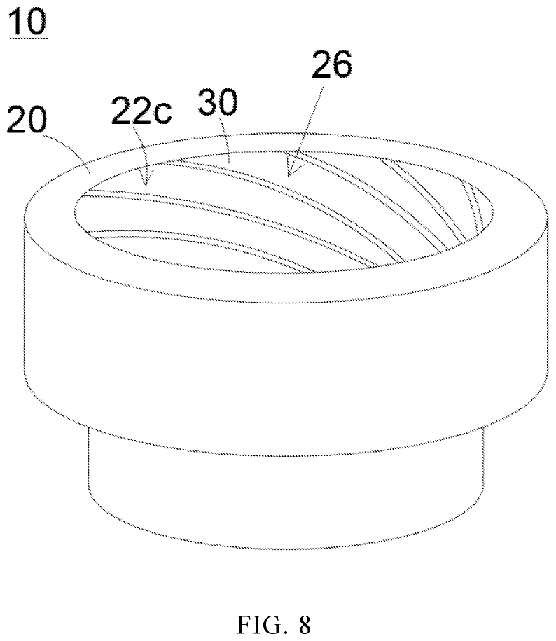

The anti-deposition object 10 of the invention is applied in a vacuum environment, as shown in FIG. 4, and contacts with a manufacturing process substance 110 used or discharged during a manufacturing process performed by a manufacturing process equipment 100 in the vacuum environment, wherein the vacuum environment is not limited to a specific vacuum degree, and could be determined according to requirements of the manufacturing process equipment 100. The fluorine coating layer 30 covers the microstructures 27 of the laser-treated surface 22b of the main structure 20 to form the anti-deposition surface 22c. The anti-deposition surface 22c of the anti-deposition object 10 of the invention could be located on the entire main structure 20 or a part 24 of the main structure 20, for example. Wherein, the part 24 could be a position where deposition of manufacturing process substances usually occurs, for example, a non-planar position or a non-horizontal position such as a curved part or an inclined part, for example but not limited to an inner wall surface or an outer wall surface. Therefore, in the invention, the part 24 is, for example, a curved part (as shown in FIG. 5) or an inclined part (as shown in FIG. 6) of the main structure 20, but the invention is not limited thereto. The fluorine coating layer 30 of the invention could also cover a planar part (as shown in FIG. 7) of the main structure 20. In addition, the main structure 20 of the anti-deposition object 10 of the invention is, for example, an outlet pipe (as shown in FIGS. 5 to 7) of the manufacturing process equipment 100 or a pipe fitting (as shown in FIGS. 5 to 7) or a component (a Holweck pump part with a helical diversion groove 26 shown in FIG. 8) of a peripheral (such as a vacuum air pump) of the manufacturing process equipment 100. Although the above-mentioned various forms of the main structure 20 of the anti-deposition object 10 are listed, the invention is not limited thereto, all forms of objects that could be applied in a vacuum environment belong to a scope of protection claimed by the invention. For example, the anti-deposition object 10 and the main structure 20 thereof of the invention could also be, for example, cavities or parts of a vacuum pump, such as a rotor blade and/or a stator blade of a turbomolecular vacuum pump (TMP). For example, the anti-deposition object 10 and the main structure 20 thereof of the invention could also be, for example, cavities or parts of a valve structure. In short, the invention is capable of optionally performing the laser surface treatment step (step S20) by using the laser 42 on the initial surface 22a of all objects that may be in contact with the manufacturing process substance 110 to form the microstructures 27, and covering the microstructures 27 by the fluorine coating layer 30 to form the anti-deposition surface 22c. Even, a form of the main structure 20 of the anti-deposition object 10 of the invention could also be, for example, a chamber wall or a component of a process chamber.

One of the characteristics of the laser-treated anti-deposition object 10 of the invention lies in the microstructures 27 of the main structure 20 being covered by the fluorine coating layer 30, so the fluorine coating layer 30 could replace the initial surface 22a or the laser-treated surface 22b of the main structure 20 to contact with the manufacturing process substance 110 used or discharged during the manufacturing process performed by the manufacturing process equipment 100. Wherein the fluorine coating layer 30, for example, could cover the laser-treated surface 22b of the main structure 20 by a coating method, wherein the coating method is, for example, but not limited to spray coating, brush coating, dip coating or wipe coating. Wherein the invention could, for example, directly immerse the main structure 20 formed with the microstructures 27 in the liquid (fluid state) fluorine coating layer 30 to coat the fluorine coating layer 30 on the microstructures 27 of the laser-treated surface 22b of the main structure 20, wherein an immersing time is, for example, about 1 minute, but it is not limited thereto, as long as the fluorine coating layer 30 is capable of covering the microstructures 27, any immersing time belongs to a scope of protection claimed by the invention. The invention is capable of increasing an adherence between the fluorine coating layer 30 and the laser-treated surface 22b of the main structure 20 by forming a rib-shaped rough structure (that is, the microstructure 27) on the main structure 20 and by increasing a hydrophilicity of the main structure 20. Taking the main structure 20 made of stainless steel as an example, the initial surface 22a of stainless steel is hydrophilic, and after the laser surface treatment step (step S20) by using the laser 42, a hydrophilicity of the laser-treated surface 22b of stainless steel will be further enhanced. That means, if the initial surface 22a is hydrophilic, the laser-treated surface 22b will be more hydrophilic; if the initial surface 22a is hydrophobic, the laser-treated surface 22b will be more hydrophobic. The invention is capable of increasing an adherence between the fluorine coating layer 30 and the laser-treated surface 22b of the main structure 20. Wherein, the invention could also perform a polishing treatment on the initial surface 22a before performing the laser surface treatment step (step S20) by using the laser 42 on the initial surface 22a of the main structure 20 to make the initial surface 22a become a polished surface, thereby improving uniformity and consistency of the laser-treated surface 22b in subsequent processes, thus capable of further increasing the contact angle. Although the polishing treatment is used as an example above, the invention is not limited thereto, as long as the initial surface 22a of the main structure 20 could be homogenized or planarized, any treatment belongs to a scope of protection claimed by the invention, so no further description is provided herein.

In the invention, after the liquid (fluid state) fluorine coating layer 30 is coated on the laser-treated surface 22b of the main structure 20, it could optionally be subjected to a self-condensation reaction at room temperature for about 1 to 7 days or subjected to a self-condensation reaction at 40 degrees Celsius to 60 degrees Celsius for about 1 to 24 hours, that is, the fluorine coating layer 30 is solidified on the laser-treated surface 22b of the main structure 20 to form the solidified fluorine coating layer 30. Wherein, the invention could, for example, immerse the main structure 20 with the microstructures 27 in the liquid (fluid state) fluorine coating layer 30 for about 1 minute, after taking the main structure 20 out, bake the main structure 20 at a temperature of 50 degrees Celsius for about 1 minute to 24 hours to carry out a self-condensation reaction on the main structure 20. A thickness of the fluorine coating layer 30 could range from 0.1 μm to 30 μm, and could be any numerical interval or upper and lower endpoint values in this range, for example, from 1 μm to 10 μm. Physical and chemical properties of the fluorine coating layer 30 are superior to original physical and chemical properties of the laser-treated surface 22b of the main structure 20. For example, in a vacuum environment, the fluorine coating layer 30 (i.e., the anti-deposition surface 22c) has the contact angle θ with the manufacturing process substance 110 higher than those of the initial surface 22a and the laser-treated surface 22b of the main structure 20, that is, the contact angle θ (range is about 99° to 150.2°, and could be any numerical interval or upper and lower endpoint values in this range, such as 150°) between the fluorine coating layer 30 and the manufacturing process substance 110 is higher than the contact angle θ (range is approximately 89 to 95 degrees) between the initial surface 22a and the manufacturing process substance 110. In the invention, by coating the fluorine coating layer 30 with the high contact angle θ on vacuum components is capable of preventing the vacuum components from depositing, and further capable of achieving effects of self-cleaning and easy-cleaning. The fluorine coating layer 30 has a hardness similar to or higher than those of the initial surface 22a and the laser-treated surface 22b of the main structure 20, that is, a hardness of the fluorine coating layer 30 (ranging from about 8H to 9H, and could be any numerical interval or upper and lower endpoint values in this range) is close to, the same as or higher than a hardness of the initial surface 22a of the main structure 20 (ranging from about 4H to 6.5H). In the invention, by coating the fluorine coating layer 30 with a high hardness on vacuum components is capable of preventing the vacuum components from being scratched by impact of manufacturing process substances such as particles. An adherence between the fluorine coating layer 30 and the laser-treated surface 22b of the main structure 20 (cross-cut test range is about 4B to 5B) is higher than a contact force of the manufacturing process substance 110 applied to the fluorine coating layer 30 (for example, external forces or adsorption forces impacting the fluorine coating layer 30 when the manufacturing process substance 110 is discharged), thereby the fluorine coating layer 30 of the invention has excellent adherence to the main structure 20 to avoid peeling off during the manufacturing process. Compared with the initial surface 22a of the main structure 20, the fluorine coating layer 30 has a higher resistance to acid corrosion and plasma etching, thereby the fluorine coating layer 30 of the invention is capable of protecting vacuum components from acid corrosion and free radicals erosion. The fluorine coating layer 30 covers or even conformally covers a rough surface of the main structure 20 (i.e., the laser-treated surface 22b with the microstructures 27), for example. In addition, the fluorine coating layer 30 of the invention is capable of withstanding relatively high temperatures, an operating temperature range thereof is quite wide, and a temperature tolerance could be as high as about 600 degrees Celsius. An operating temperature range of the fluorine coating layer 30 is, for example, less than or equal to about 600 degrees Celsius, preferably, for example, from about 260 degrees Celsius to 600 degrees Celsius, and could be any numerical interval or upper and lower endpoint values of less than or equal to 600 degrees Celsius. In contrast, conventional water-repellent coatings or anti-fouling coatings usually cannot withstand high temperatures. For example, a temperature for using conventional Teflon is lower than 260 degrees Celsius. Not to mention a hardness of conventional water-repellent coatings or anti-fouling coatings is only about 1H to 3H, for example, a hardness of conventional Teflon is 1H to 2H. It could be known from this that conventional water-repellent layers or anti-fouling layers cannot withstand high temperature, high vacuum, high corrosion, high impact and high deposition environment when the manufacturing process equipment 100 performs a semiconductor manufacturing process. In other words, the anti-deposition object 10 of the invention is capable of saving capital and manpower for frequent maintenance by combining the fluorine coating layer 30 with the main structure 20.

A composition of the fluorine coating layer 30 of the invention could be, for example, composed of fluorocarbons accounting for about 0.01˜20 wt %, alkoxysilanes accounting for about 5˜50 wt %, catalytic additives accounting for about 0.01˜20 wt % and solvents accounting for about 10˜90 wt %. The fluorocarbons are, for example, fluorine-containing monomers or polymers containing 1-20 carbon atoms. The fluorocarbons are, for example, fluorine-containing monomers containing from about 3 to about 20 carbon atoms and at least one terminal trifluoromethyl. For example, the fluorocarbons are selected from, for example, a group consisting of perfluoroalkanes (PFAS), fluorochlorocarbons (CFCs), hydrofluorocarbons (HFCs), fluoropolymers (PTFE) and hydrofluorochlorocarbons (HCFCs). The alkoxysilanes are selected from, for example, a group consisting of alkoxysilane oligomer, alkoxysilane compound, alkoxysilane polymer, alkylsiloxane oligomer, alkylsiloxane compound, alkylsiloxane polymer, amino-alkyl siloxane oligomer, amino-alkyl siloxane compound and amino-alkyl siloxane polymer. The catalytic additives are selected a group consisting of metals, metal oxides, phosphates and carboxylates of platinum, titanium, tin, zinc, aluminum, silver, calcium, magnesium, potassium, sodium, nickel, chromium, molybdenum, vanadium, copper, iron, cobalt, germanium, hafnium, lanthanum, lead, ruthenium, tantalum, tungsten and zirconium. For example, the catalytic additives are selected from a group consisting of silicon oxides, aluminum oxides, titanium oxides, iron oxides, magnesium oxides, molybdenum oxides, calcium oxides and calcium chlorides, and are, for example, nano-sized. But the invention is not limited thereto. Micronano-sized or even micron-sized catalytic additives or components belong to a scope of protection claimed by the invention. The solvents are, for example, alcohols such as ethanol, propanol, or butanol. However, the invention is not limited thereto, the solvents of the invention could be selected from a group consisting of alcohols, ketones, esters, fluoroalcohols, fluoroethers and ethers. The alkoxysilanes of the invention have reactive functional groups, and the reactive functional groups carry out a self-condensation reaction at room temperature for 1 to 7 days (for example, 7 days) or carry out a self-condensation reaction at a temperature of 40 to 60 degrees Celsius for 1 to 24 hours (for example, 24 hours). Wherein the above-mentioned reactive functional groups are, for example, hydrosilated reactive functional groups (such as hydrogen atoms of alkenyl, acryl bonded to silicon atoms), condensation reactive functional groups (such as hydroxyl, alkoxy, acyloxy) or peroxide hardening reactive functional groups (such as alkyl, alkenyl, acryl, hydroxyl). In addition, in a feasible implementation mode, a composition of the fluorine coating layer 30 of the invention could also be, for example, organic/inorganic macromolecular copolymers composed of fluorine, nano-titanium, silicon and silicon elastomer. Since a person having ordinary skill in the art to which the invention pertains should know how to select and modulate the anti-deposition object 10 of the fluorine coating layer 30 having the efficacies of the invention based on the foregoing contents of the invention, so no further details are provided herein.

A surface hardness testing method of the invention uses a hardness pencil to test a surface hardness of the fluorine coating layer 30. For example, load a hardness pencil (Mitsubishi standard pencil) on a trolley with a fixed load at an angle of 45 degrees, and then push the trolley by hand to slide over a surface of the fluorine coating layer 30 of the anti-deposition object 10 to confirm a surface hardness when being scratched by a pencil. In the anti-deposition object 10 of the invention, all surface hardness test results of the fluorine coating layer 30 covering the laser-treated surface 22b of the main structure 20 are between 8H load 1 Kg and 9H load 500 g.

The cross-cut test of the invention is performed according to ASTM D3359 method B (cross-cut method). The test method uses a cross-cut knife to draw 10×10 (100 pieces) 1 mm×1 mm small grid lines on a surface of a test sample, each drawn line should reach a bottom layer of the fluorine coating layer 30 of the anti-deposition object 10; use a brush to clean debris in a test area; use a standard adhesive tape (3M tape No. 600) or an equivalent adhesive tape to stick to the tested small grid lines, use an eraser to rub the tape vigorously to increase a contact area and a strength between the tape and the tested area, grab one end of the tape with a hand, and quickly tear off the tape at an angle of 180 degrees within 1.5 minutes plus or minus 30 seconds and observe a state of peeling off of the fluorine coating layer 30. In the anti-deposition object 10 of the invention, all results of the cross-cut test of the fluorine coating layer 30 of the invention coated on the laser-treated surface 22b of the main structure 20 are between 5B (cut edges are completely smooth, and grid edges do not have any peeling off) and 4B (small flakes at intersections of cuts, and actual damage ≤5% inside grid areas). It could be known from the results that an adhesion (adherence) of the fluorine coating layer 30 of the invention to the initial surface 22a and the laser-treated surface 22b of the main structure 20 is quite high.

An acid corrosion resistance test experiment of the invention uses 0.05 mL of 5% HCl (hydrochloric acid) to drop on a test sample, let it stand for 24 hours, and wait for the HCl solution to volatilize. During a volatilization process, a concentration of the HCl area will rise, and an effect of diffusion corrosion will increase. After 24 hours of observation, a diffusion area is corroded.

According to test results, a corrosion area (mm²) of the laser-treated surface 22b of the main structure 20 without coating the fluorine coating layer 30 is about 45.13 mm², but a corrosion area (mm²) of the laser-treated surface 22b of the main structure 20 coated with the fluorine coating layer 30 is only about 19.4 mm².

In addition, the invention has also undergone a plasma etching test, results show that under the same etching conditions (CHF₃: Ar is 1:1, 60 minutes, a rate of etching oxides is 750 nm/30 min), the fluorine coating layer 30 of the invention reliably has a resistance to plasma etching better than that of the laser-treated surface 22b of the main structure 20 (made of anodized aluminum). As for a thermal stability test (thermogravimetric analyzer, TGA test), under a test environment of heating rate being 5 degrees Celsius/min and test atmosphere being N₂, a weight of the fluorine coating layer 30 of the invention shows a steady and slow decline within a test temperature range (600 degrees Celsius), and there is no sudden weight change, showing that cracking does not occur in the fluorine coating layer 30 of the anti-deposition object 10 of the invention.

The manufacturing process performed by the manufacturing process equipment 100 is, for example, a semiconductor manufacturing process. For example, the manufacturing process performed by the manufacturing process equipment 100 is an atomic layer deposition (ALD) manufacturing process, and the manufacturing process substance 110 is titanium tetrachloride (TiCl₄), wherein the main structure 20 of the anti-deposition object 10 is, for example, a fluid delivery pipe, but not limited thereto. For example, the manufacturing process performed by the manufacturing process equipment 100 is a metalorganic chemical vapor deposition (MOCVD) manufacturing process, and the manufacturing process substance 110 is a process gas or a process exhaust gas, wherein the main structure 20 of the anti-deposition object 10 is, for example, an outlet pipe of a vacuum air pump, but not limited thereto. For example, the manufacturing process performed by the manufacturing process equipment 100 is an Al-pad manufacturing process, and the manufacturing process substance 110 is a process gas reactant or a process exhaust gas, such as selected from a group consisting of N₂, O₂, Ar, SF₆, He, HBr, CF₄, CH₄, Cl₂, BCl₃ and CHF₃, wherein the main structure 20 of the anti-deposition object 10 is, for example, a pump part and an outlet pipe with a helical diversion groove, but not limited thereto. The laser-treated anti-deposition object 10 of the invention has been tested in practice and has excellent effects in the above-mentioned manufacturing processes. For example, in the Al-pad manufacturing process, the anti-deposition object 10 of the invention is capable of extending about 20% of a maintenance cycle, so is capable of reducing capital and manpower for frequent maintenance.

In summary, the laser-treated anti-deposition object and the manufacturing method of the same of the invention have the following advantages:

(1) By performing the laser surface treatment step by the laser on the initial surface of the main structure of the vacuum component is capable of forming the laser-treated surface with a plurality of microstructures, thereby increasing hydrophilicity and roughness, which is conducive to covering the microstructures with the fluorine coating layer subsequently.

(2) By coating the high-hardness fluorine coating layer on the laser-treated surface of the vacuum component as the anti-deposition surface is capable of preventing the vacuum component from being scratched by impact of manufacturing process substances such as particles.

(3) By coating the fluorine coating layer with a high contact angle on the laser-treated surface of the vacuum component as the anti-deposition surface is capable of preventing the vacuum component from depositing, and further capable of achieving effects of self-cleaning and easy-cleaning.

(4) The fluorine coating layer has excellent adherence to the main structure with the laser-treated surface to avoid peeling off during the manufacturing process.

(5) By providing an anti-deposition object with the fluorine coating layer as the anti-deposition surface is capable of saving capital and manpower for frequent maintenance.

Note that the specification relating to the above embodiments should be construed as exemplary rather than as limitative of the present invention, with many variations and modifications being readily attainable by a person of average skill in the art without departing from the spirit or scope thereof as defined by the appended claims and their legal equivalents.

What is claimed is:

1. A laser-treated anti-deposition object, the anti-deposition object contacting with a manufacturing process substance used or discharged during a manufacturing process performed by a manufacturing process equipment in a vacuum environment, the anti-deposition object comprising:
a main structure, at least one initial surface of the main structure being subjected to a laser surface treatment step by a laser to become a laser-treated surface with a plurality of microstructures; and
a fluorine coating layer, the fluorine coating layer covering the microstructures of the laser-treated surface of the main structure in order to serve as an anti-deposition surface of the main structure, wherein the initial surface and the laser-treated surface of the main structure are hydrophilic surfaces, a hydrophilicity of the laser-treated surface is higher than a hydrophilicity of the initial surface, and the anti-deposition surface is a hydrophobic surface, so that the anti-deposition surface has a contact angle to the manufacturing process substance higher than those of the initial surface and the laser-treated surface of the main structure.

2. The laser-treated anti-deposition object as claimed in claim 1, wherein the fluorine coating layer covers the laser-treated surface of the main structure by coating, so that the fluorine coating layer is capable of covering the microstructures of the main structure.

3. The laser-treated anti-deposition object as claimed in claim 1, wherein the fluorine coating layer covers the microstructures of the main structure conformally.

4. The laser-treated anti-deposition object as claimed in claim 1, wherein the initial surface of the main structure is irradiated by the laser with an energy density to form the laser-treated surface with the microstructures, wherein the energy density ranges from 0.01 W/cm² to 110 W/cm².

5. The laser-treated anti-deposition object as claimed in claim 1, wherein a scanning speed of the laser ranges from 50 mm/s to 100 mm/s, a scanning frequency of the laser ranges from 10 kHz to 40 kHz, a pulse width of the laser ranges from 20 ns to 200 ns, and a laser scanning interval of the laser ranges from 10 μm to 200 μm in order to form the microstructures on the main structure.

6. The laser-treated anti-deposition object as claimed in claim 1, wherein a power of the laser ranges from 10 watts to 100 watts, and a wavelength of the laser ranges from 380 nm to 1400 nm in order to form the microstructures on the main structure.

7. The laser-treated anti-deposition object as claimed in claim 1, wherein a material of the main structure is stainless steel.

8. The laser-treated anti-deposition object as claimed in claim 1, wherein the main structure is an outlet pipe fitting of the manufacturing process equipment or a pipe fitting or a component of a peripheral equipment of the manufacturing process equipment.

9. The laser-treated anti-deposition object as claimed in claim 1, wherein the anti-deposition surface is located on a part of the main structure, and the part is an inclined part, a planar part or a curved part of the main structure.

10. The laser-treated anti-deposition object as claimed in claim 1, wherein the anti-deposition surface has an acid corrosion resistance and a plasma etching resistance higher than those of the initial surface of the main structure.

11. The laser-treated anti-deposition object as claimed in claim 1, wherein the anti-deposition surface has a hardness similar to or higher than that of the initial surface of the main structure.

12. The laser-treated anti-deposition object as claimed in claim 1, wherein a surface roughness of the laser-treated surface with the microstructures is higher than a surface roughness of the initial surface of the main structure.

13. The laser-treated anti-deposition object as claimed in claim 12, wherein the initial surface of the main structure is a polished surface after performing a polishing treatment.

14. The laser-treated anti-deposition object as claimed in claim 1, wherein a composition of the fluorine coating layer is composed of fluorocarbons accounting for 0.01˜20 wt %, alkoxysilanes accounting for 5˜50 wt %, catalytic additives accounting for 0.01˜20 wt % and solvents accounting for 10˜90 wt %.

15. The laser-treated anti-deposition object as claimed in claim 1, wherein the manufacturing process performed by the manufacturing process equipment is an atomic layer deposition (ALD) manufacturing process, a metalorganic chemical vapor deposition (MOCVD) manufacturing process or an Al-pad manufacturing process.

16. The laser-treated anti-deposition object as claimed in claim 1, wherein the contact angle of the anti-deposition surface ranges from 99 degrees to 150.2 degrees.

17. A manufacturing method of a laser-treated anti-deposition object, the anti-deposition object contacting with a manufacturing process substance used or discharged during a manufacturing process performed by a manufacturing process equipment in a vacuum environment, the manufacturing method comprising following steps of:
providing a main structure, wherein the main structure has at least one initial surface;
performing a laser surface treatment step on the initial surface of the main structure by using a laser, so that the initial surface becoming a laser-treated surface with microstructures; and
performing a fluorine coating step for covering the microstructures of the laser-treated surface of the main structure by a fluorine coating layer in order to form an anti-deposition surface on the main structure, wherein the initial surface and the laser-treated surface of the main structure are hydrophilic surfaces, a hydrophilicity of the laser-treated surface is higher than a hydrophilicity of the initial surface, and the anti-deposition surface is a hydrophobic surface, so that the anti-deposition surface has a contact angle to the manufacturing process substance higher than those of the initial surface and the laser-treated surface of the main structure.

18. The manufacturing method of the laser-treated anti-deposition object as claimed in claim 17, wherein the fluorine coating layer covers the microstructures of the main structure conformally.

19. The manufacturing method of the laser-treated anti-deposition object as claimed in claim 17, wherein in the laser surface treatment step, an energy density of the laser irradiating the initial surface of the main structure ranges from 0.01 W/cm² to 110 W/cm² in order to form the microstructures on the main structure.

20. The manufacturing method of the laser-treated anti-deposition object as claimed in claim 17, wherein a scanning speed of the laser ranges from 50 mm/s to 100 mm/s, a scanning frequency of the laser ranges from 10 kHz to 40 kHz, a pulse width of the laser ranges from 20 ns to 200 ns, and a laser scanning interval of the laser ranges from 10 μm to 200 μm in order to form the microstructures on the main structure.

21. The manufacturing method of the laser-treated anti-deposition object as claimed in claim 17, wherein a power of the laser ranges from 10 watts to 100 watts, and a wavelength of the laser ranges from 380 nm to 1400 nm in order to form the microstructures on the main structure.
